(19) United States
(12) Patent Application Publication
(10) Pub. No.: US 2011/0169138 A1
(43) Pub. Date: Jul. 14, 2011

(54) TECHNIQUES FOR ACHIEVING LOW RESISTANCE CONTACTS TO NONPOLAR AND SEMIPOLAR P-TYPE (Al,Ga,In)N

(75) Inventors: You-Da Lin, Goleta, CA (US); Arpan Chakraborty, Goleta, CA (US); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 12/909,702

(22) Filed: Oct. 21, 2010

Related U.S. Application Data
(60) Provisional application No. 61/257,759, filed on Nov. 3, 2009.

(51) Int. Cl. H01L 29/20; H01L 21/20; H01L 21/28

(52) U.S. Cl. 257/615; 438/478; 438/604; 257/E21.09; 257/E29.089; 257/E21.158

(57) ABSTRACT

A method of fabricating a p-type contact on a nonpolar or semipolar (Al,Ga,In)N device, includes the steps of growing a p-type layer on an (Al,Ga,In)N device, wherein the (Al,Ga,In)N device is a nonpolar or semipolar (Al,Ga,In)N device, and the p-type layer is a nonpolar or semipolar (Al,Ga,In)N layer; and cooling the p-type layer down, in the presence of Bis(Cyclopentadienyl)Magnesium (Cp2Mg), to form a magnesium-nitride (MgₓN_{y}) layer on the p-type layer. A metal deposition is performed to fabricate a p-type contact on the p-type layer of the (Al,Ga,In)N device, after the cooling step, wherein the p-type contact has a contact resistivity lower than a p-type contact of a polar (Al,Ga,In)N device with substantially similar composition. A hydrogen chloride (HCl) pre-treatment of the p-type layer may be performed, after the cooling step and before the metal deposition step.

### CROSS REFERENCE TO RELATED APPLICATIONS

This application claims priority under 35 U.S.C. §119(e) to co-pending and commonly-assigned U.S. Provisional Patent Application Ser. No. 61/257,759, entitled “TECHNIQUES FOR ACHIEVING LOW RESISTANCE CONTACTS TO SEMIPOLAR P-TYPE (Al,Ga,In)N,” filed on Nov. 3, 2009, by You-Da Lin, Arpan Chakraborty, Shuji Nakamura, and Steven P. DenBaars, attorney's docket number 30794.338-US-P1, which application is incorporated by reference herein.

This application is related to the following co-pending and commonly-assigned U.S. patent application:

U.S. Provisional Application Ser. No. 61/257,757, filed on Nov. 3, 2010, by Arpan Chakraborty, Hsun Chih Kuo, Shuji Nakamura, and Steven P. DenBaars, entitled “CONTACT TO P-TYPE NITRIDE SEMICONDUCTOR,” attorney's docket number 30794.336-US-P1 (2010-266);

which application is incorporated by reference herein.

### STATEMENT REGARDING FEDERALLY SPONSORED RESEARCH AND DEVELOPMENT

This invention was made with Government support under Grant No FA8718-08-0005 awarded by DARPA-VIGIL. The Government has certain rights in this invention.

### BACKGROUND OF THE INVENTION

1. Field of the Invention

This invention relates to techniques for achieving low resistance contacts to p-type (Al,Ga,In)N, and to nonpolar and semipolar p-type (Al,Ga,In)N in particular.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

(Al,Ga,In)N optoelectronic and electronic devices (also referred to as “Group-III nitride”, “III-nitride”, or just “nitride” devices) are typically grown on c-plane sapphire substrates, SiC substrates or bulk (Al,Ga,In)N substrates. In each instance, the devices are usually grown along their polar (0001) c-axis orientation, i.e., a c-plane direction.

However, conventional polar (Al,Ga,In)N based devices suffer from undesirable quantum-confined Stark effect (QCSE), due to the existence of strong piezoelectric and spontaneous polarizations. For example, GaN and its alloys are the most stable in a hexagonal würtzite crystal structure, in which the structure is described by two (or three) equivalent basal plane axes that are rotated 120° with respect to each other (the a-axis), all of which are perpendicular to a unique c-axis. Group III atoms, such as Ga, and nitrogen (N) atoms occupy alternating c-planes along the crystal's c-axis. The symmetry elements included in the würtzite structure dictate that (Al,Ga,In)N devices possess a bulk spontaneous polarization along this c-axis, and the würtzite structure exhibits piezoelectric polarization, which give rise to restricted carrier recombination efficiency, reduced oscillator strength, and red-shifted emission.

One approach to eliminating the spontaneous and piezoelectric polarization effects in (Al,Ga,In)N devices is to grow the devices on nonpolar planes of the crystal, which are orthogonal to the c-plane of the crystal. For example, with regard to GaN, such planes contain equal numbers of Ga and N atoms, and are charge-neutral. Furthermore, subsequent nonpolar layers are crystallographically equivalent to one another, so the crystal will not be polarized along the growth direction. Two such families of symmetry-equivalent nonpolar planes in GaN are the {11-20} family, known collectively as a-planes, and the {1-100} family, known collectively as m-planes.

Another approach to reducing or possibly eliminating the polarization effects in GaN optoelectronic devices is to grow the devices on semipolar planes of the crystal. The term semipolar planes can be used to refer to a wide variety of planes that possess two nonzero h, i, or k Miller indices, and a nonzero 1 Miller index. Some examples of semipolar planes in the würtzite crystal structure include, but are not limited to, {10-12}, {20-21}, and {10-14}. The crystal's polarization vector lies neither within such planes or normal to such planes, but rather lies at some angle inclined relative to the plane's surface normal.

Conventional state-of-the-art p-contact layers for devices grown on nonpolar and semipolar (Al,Ga,In)N substrates are usually capped with a thin layer of p⁺-GaN to improve contact resistance. On the other hand, conventional polar (c-plane) (Al,Ga,In)N devices show improved contact resistance with pre-treatments, such as Boiled Aqua Regia (BAR), BAR followed by (NH₄)₂S, etc. See, for example, references [1-6] set forth below and incorporated by reference herein.

Consequently, there is a need in the art for improved techniques for achieving low resistance contacts to nonpolar and semipolar p-type (Al,Ga,In)N layers in particular. The present invention satisfies this need using a Bis(Cyclopentadienyl)Magnesium (Cp2Mg) flow during growth cool down until 700° C., to form metalorganic chemical vapor deposition (MOCVD) grown magnesium-nitride (Mg—N) layers to reduce contact resistance. Moreover, the present invention satisfies this need using a hydrogen chloride (HCl) pre-treatment for p-type layers before p-contact metallization. Prior art conventional nonpolar (Al,Ga,In)N devices have not used these techniques.

### SUMMARY OF THE INVENTION

The present invention describes techniques to fabricate low resistance p-type contacts on nonpolar and semipolar (Al,Ga,In)N based devices. The invention features novel epitaxial growth techniques and pre-treatment prior to contact metal deposition, to improve electrical properties of (Al,Ga,In)N based devices, including light emitting diodes (LEDs), laser diodes (LDs), high electron mobility transistors, and other electrically operating devices. Some of the key features include using post-growth Cp2Mg-flow during cool down and chemical pre-treatment before p-contact metallization steps, in order to reduce contact resistance.

A method of fabricating a p-type contact on a nonpolar or semipolar (Al,Ga,In)N device, includes the steps of growing a p-type layer on an (Al,Ga,In)N device, wherein the (Al,Ga,In)N device is a nonpolar or semipolar (Al,Ga,In)N device, and the p-type layer is a nonpolar or semipolar (Al,Ga,In)N layer; and cooling the p-type layer down, in the presence of Bis(Cyclopentadienyl)Magnesium (Cp2Mg), to form a magnesium-nitride (MgₓN_{y}) layer on the p-type layer. A metal deposition is performed to fabricate a p-type contact on the p-type layer of the (Al,Ga,In)N device, after the cooling step, wherein the p-type contact has a contact resistivity lower than a p-type contact of a polar (Al,Ga,In)N device with a substantially similar composition. A hydrogen chloride (HCl) pre-treatment of the p-type layer may be performed, after the cooling step and before the metal deposition step.

The cooling step is performed until a temperature of at least 700 degrees Celsius is reached, and more preferably, the cooling step is performed until a temperature of at least 500 degrees Celsius is reached. Moreover, the cooling step is performed in a nitrogen (N₂) and ammonia (NH₃) ambient environment.

The resulting (Al,Ga,In)N device includes a p-type contact fabricated on a p-type layer of the (Al,Ga,In)N device, wherein the (Al,Ga,In)N device is a nonpolar or semipolar (Al,Ga,In)N device, the p-type layer is a nonpolar or semipolar (Al,Ga,In)N layer, and the p-type contact has a contact resistivity lower than a p-type contact of a polar (Al,Ga,In)N device with a substantially similar composition. Specifically, the p-type contact has a contact resistivity less than 2×10⁻³ Ohm-cm⁻², wherein the p-type layer has an oxygen concentration sufficiently low to achieve the contact resistivity.

### BRIEF DESCRIPTION OF THE DRAWINGS

Referring now to the drawings in which like reference numbers represent corresponding parts throughout:

FIG. 1(a) is a flowchart showing the process steps performed in one embodiment of the present invention, and FIG. 1(b) is a cross-sectional schematic of an exemplary resulting device.

FIG. 2 is a graph of contact resistivity (ohm-cm⁻²) versus Cp2Mg flow during growth cool down in standard cubic centimeters per minute (sccm).

FIG. 3 is a graph of X-ray photoelectron spectroscopy (XPS) data of a nonpolar p-GaN contact layer sample fabricated without Cp2Mg flow during growth cool down, plotting counts per second (CPS) (×10⁴) as a function of binding energy in electron volts (eV).

FIG. 4 is a graph of XPS data of the nonpolar p-GaN contact layer sample fabricated using Cp2Mg flow during cool down, plotting CPS (×10⁴) versus binding energy in eV.

FIG. 5 is a graph that plots contact resistivity (ohm-cm⁻²) for p-GaN contacts prepared using HCl, Aqua Regia (AR), boiling Aqua Regia (BAR), and BAR and (NH₄)₂S pre-treatments, to provide a comparison of polar (c-plane) and non-polar (m-plane) p-GaN contact resistivity with different pre-treatments.

FIGS. 6(a)-6(f) are graphs of XPS data of c-plane and m-plane p-GaN with different pre-treatments, plotting CPS (×10⁴) versus binding energy in eV, wherein FIG. 6(a) is a graph of XPS data for a c-plane p-GaN contact layer fabricated using BAR and (NH₄)₂S pre-treatment, FIG. 6(b) is a graph of XPS data for an m-plane p-GaN contact layer fabricated using BAR and (NH₄)₂S pre-treatment, FIG. 6(c) is a graph of XPS data for a c-plane p-GaN contact layer fabricated using BAR pre-treatment, FIG. 6(d) is a graph of XPS data for an m-plane p-GaN contact layer fabricated using BAR pre-treatment, FIG. 6(e) is a graph of XPS data for a c-plane p-GaN contact layer fabricated using HCl pre-treatment, FIG. 6(f) is a graph of XPS data for an m-plane p-GaN contact layer fabricated using HCl pre-treatment.

FIG. 7 is a graph of current-voltage (I-V) characteristics that shows the difference between the two transmission line measurement (TLM) pads with the smallest separation before, and after, applying the present invention (before and after post-growth Cp2Mg-flow during cool down and HCl treatment).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The purpose of the present invention was to develop low contact resistance for nonpolar and semipolar (Al,Ga,In)N optoelectronic and electronic devices. This invention has the following advantages compared to traditional (Al,Ga,In)N devices.

1. The use of Cp2Mg flow during growth cool down until 650-700° C., in an N₂ and NH₃ ambient environment at atmospheric pressure, resulted in the formation of an Mg—N layer on the surface of a nonpolar or semipolar p-type (Al,Ga,In) layer, for example, a p-GaN layer, and reduced the p-contact resistance. The presence of Mg and N during the cool down prevented O incorporation on the surface of the p-GaN layer and also prevented N vacancy formation. The reduction in the N vacancy formation reduced the p-contact resistance, because the N vacancy acts as a surface donor in the (Al,Ga,In)N system.

2. The use of HCl pre-treatment for a nonpolar or semipolar p-type (Al,Ga,In)N layer, such as a p-GaN layer, before p-contact metallization, resulted in reduced p-contact resistance. This Chlorine (Cl) ion based pre-treatment resulted in lowering of the surface O concentration, resulting in improved contact resistance. The MgₓN_{y} seems to ride on the surface of the p-GaN layer, thereby preventing any native oxide or nitrogen vacancy formation. Upon HCl pretreatment prior to metallization, the MgₓN_{y} layer is partially or completely removed, and the metal of the p-contact makes ohmic contact to the p-GaN layer.

Technical Description

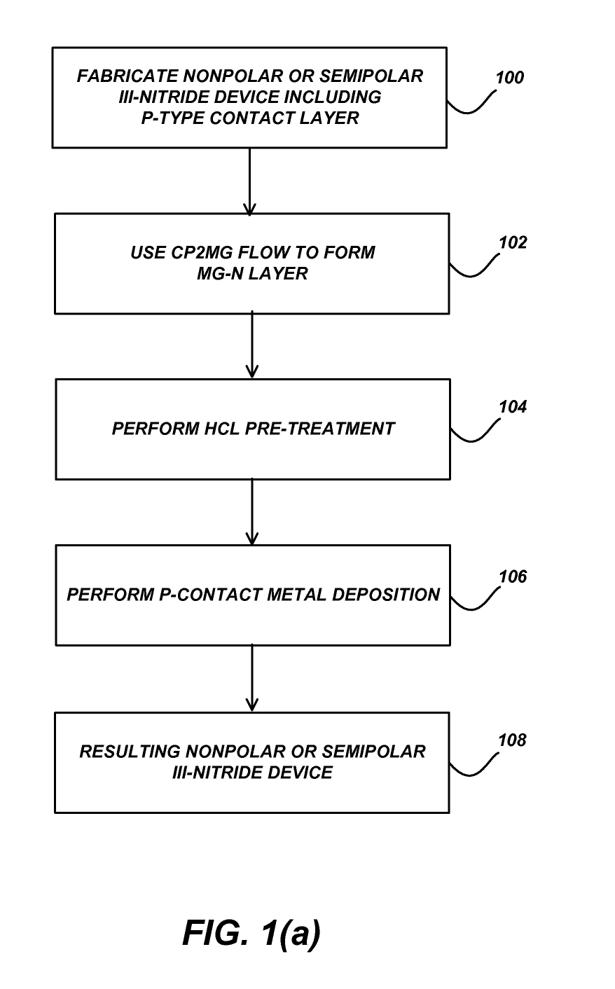

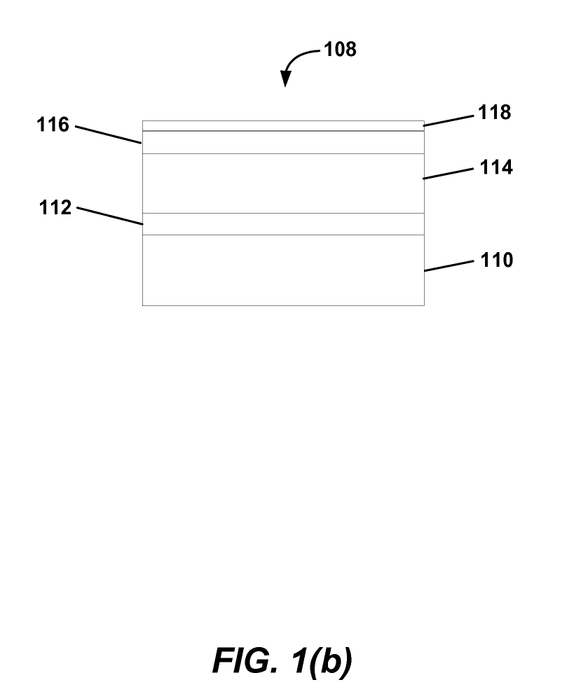

FIG. 1(a) is a flowchart showing the process steps performed in one embodiment of the present invention, in order to achieve low resistance contact to nonpolar and semipolar p-type (Al,Ga,In)N. Specifically, FIG. 1(a) shows the following steps.

Block 100 represents Step 1: the fabrication of a sample, namely a non-polar or semipolar (Al,Ga,In)N optoelectronic or electronic device, wherein one of the last steps in the fabrication is the growth of a nonpolar or semipolar p-type (Al,Ga,In)N layer, for example, a nonpolar or semipolar p-GaN layer.

Block 102 represents Step 2: the use of Cp2Mg flow after the growth of the p-GaN layer. The sample is cooled down in an N₂ and NH₃ ambient environment, and a small amount of Cp2Mg is flowed until a temperature of 700° C. is reached. This results in the formation of an Mgₓ-N_{y} layer on the p-GaN layer, prior to p-contact metallization, which results in lower contact resistance.

Block 104 represents Step 3: an HCl chemical pre-treatment is performed on the p-GaN layer, following Step 2 or without Step 2 (the HCL treatment can also be applied to the p-GaN layer without performing Step 2 first).

Block 106 represents Step 4: after Step 3, p-contact metallization, i.e., metal deposition, on the p-GaN layer, resulting in low O contamination and reduced contact resistance for the device.

Finally, following Step 4, Block 108 represents the end result of the process, namely the resulting nonpolar or semipolar (Al,Ga,In)N device having reduced contact resistance, including the p-contact on the nonpolar or semipolar p-type (Al,Ga,In)N layer of the nonpolar or semipolar (Al,Ga,In)N device. The device may also include an Mgₓ-N_{y} layer on the nonpolar or semipolar p-type (Al,Ga,In)N layer, or the Mgₓ-N_{y} layer may be completely or partially removed.

FIG. 1(b) is a cross-sectional schematic of the end result 108, namely the resulting nonpolar or semipolar (Al,Ga,In)N device 108 having reduced contact resistance. In FIG. 1(b), wherein the structure is merely exemplary and not considered to be limiting, the device 108 at least includes a nonpolar or semipolar n-type (Al,Ga,In)N layer 110, a nonpolar or semipolar (Al,Ga,In)N active layer 112, a nonpolar or semipolar p-type (Al,Ga,In)N layer 114, an optional Mgₓ-N_{y} layer 116 (which may be partially or completely removed) and a p-contact 118. Other embodiments may not include these specific layers and may include other layers, such as substrates and the like.

Experimental Results

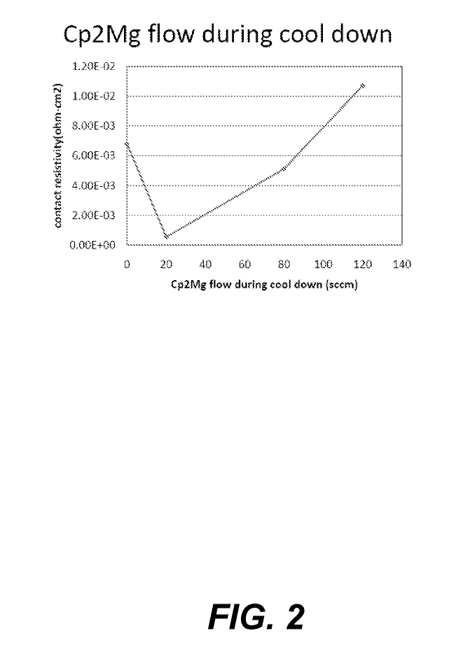

The data in FIGS. 2-7 and Table 1 are experimental results for a nonpolar p-GaN layer on a p-n diode structure device. However, the present invention can apply to any nonpolar or semipolar device with p-type contacts on p-type layers.

FIG. 2 is a graph of contact resistivity (ohm-cm⁻²) versus Cp2Mg flow during growth cool down in standard cubic centimeters per minute (sccm). Specifically, FIG. 2 shows low contact resistivity of a nonpolar p-GaN contact layer fabricated using 20 sccm Cp2Mg flow during growth cool down following the p-type GaN contact layer growth.

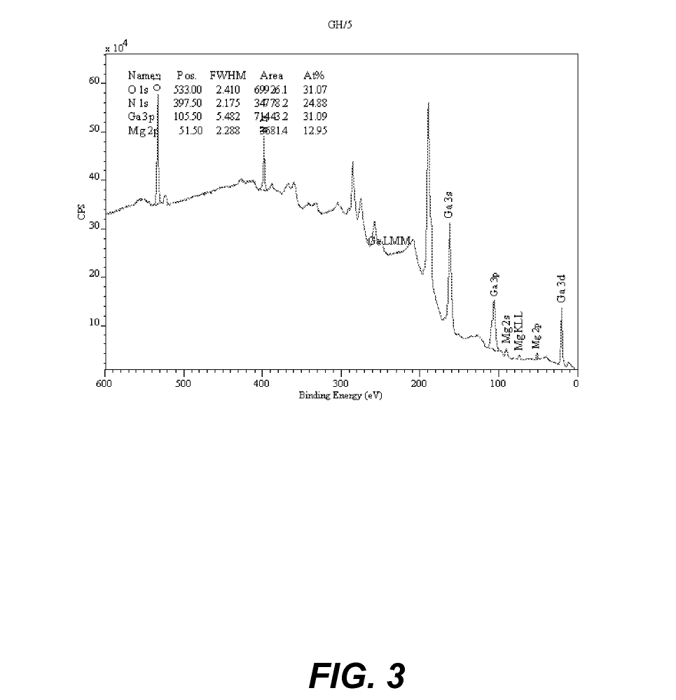

FIG. 3 is a graph of XPS data of a nonpolar p-GaN contact layer sample fabricated without Cp2Mg flow during growth cool down, plotting CPS (×10⁴) as a function of binding energy in eV, wherein information corresponding to the Oxygen (O) 15 peak, Nitrogen (N) 1s peak, Gallium (Ga) 3p peak, and Magnesium (Mg) 2p peak is shown, the information is peak emission position (pos.) in eV, peak emission full width at half maximum (FWHM) in eV, area of the emission's peak (A) in eV, and percent content of the O, N, Ga, and Mg (At %), and Mg 2s, Ga 3s, and Ga 3d peaks, and Ga LMM and Mg KLL auger transition peaks are also shown.

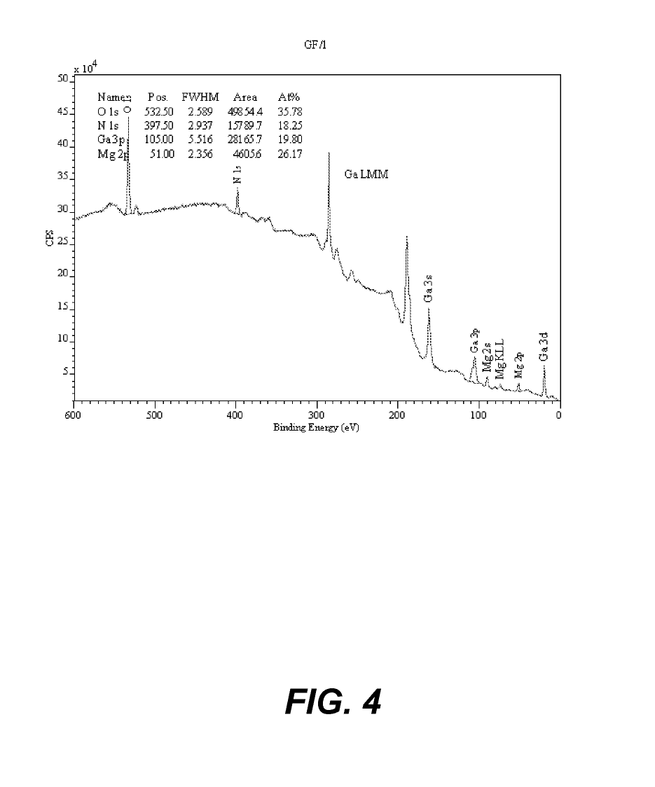

FIG. 4 is a graph of XPS data of the same nonpolar p-GaN contact layer sample structure as in FIG. 3, fabricated using Cp2Mg flow during cool down, plotting CPS (×10⁴) versus binding energy in eV. FIG. 4 shows reduced O and increased Mg on the surface of the p-GaN contact layer, wherein information corresponding to the O 1s peak, N 1s peak, Ga 3p peak, and Mg 2p peak is shown, the information is peak emission position (pos.) in eV, peak emission FWHM in eV, area of the emission's peak (A) in eV, and percent content of the O, N, Ga, and Mg (At %), and Mg 2s, Ga 3s, and Ga 3d peaks, and Ga LMM and Mg KLL auger transition peaks are also shown.

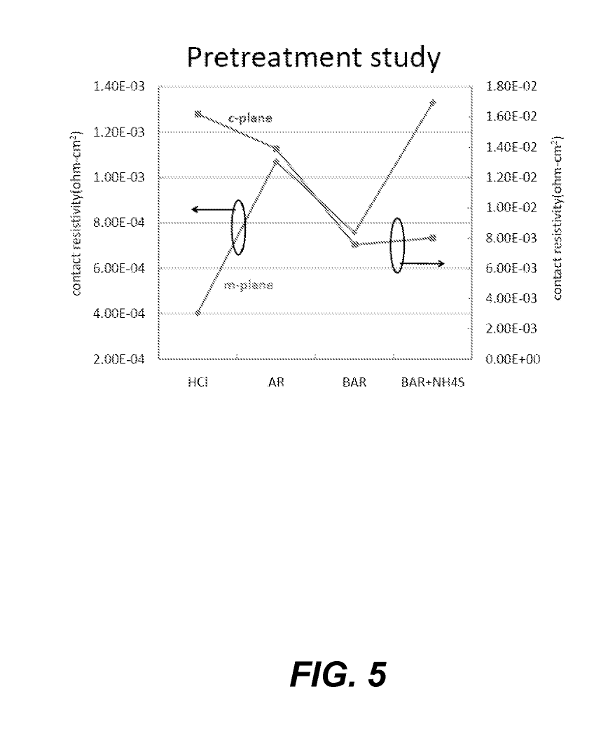

FIG. 5 is a graph that plots contact resistivity (ohm-cm⁻²) for p-GaN contacts prepared using HCl, Aqua Regia (AR), boiling Aqua Regia (BAR), and BAR and (NH₄)₂S pre-treatments, to provide a comparison of polar (c-plane) and non-polar (m-plane) p-GaN contact resistivity with different pre-treatments. Specifically, FIG. 5 illustrates that a nonpolar p-type III-nitride contact layer may have a contact resistivity lower than a polar p-type III-nitride contact layer, wherein the nonpolar and polar III-nitride contact layers have the same III-nitride compositions.

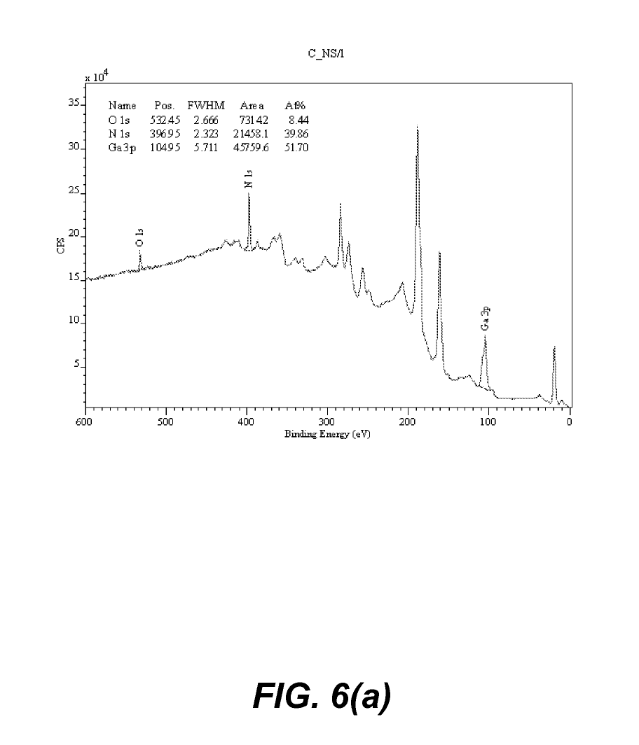

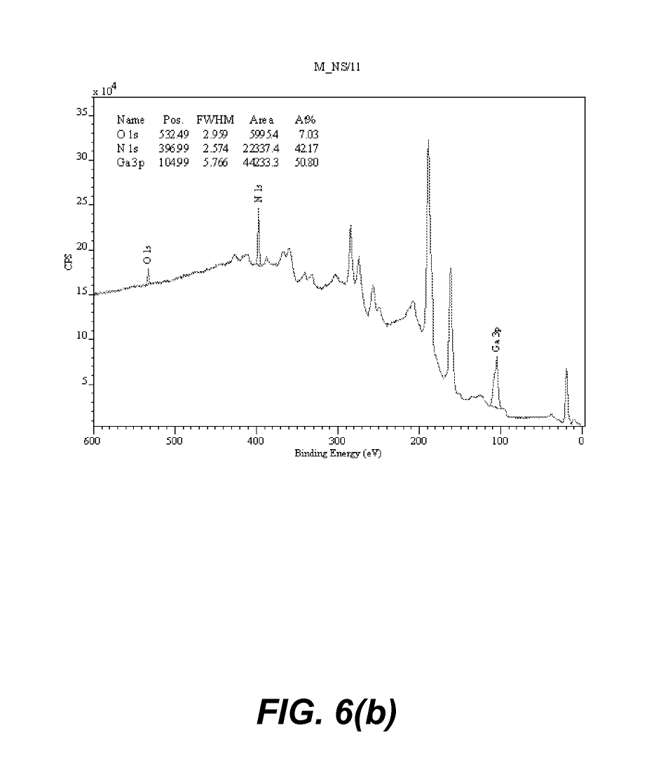

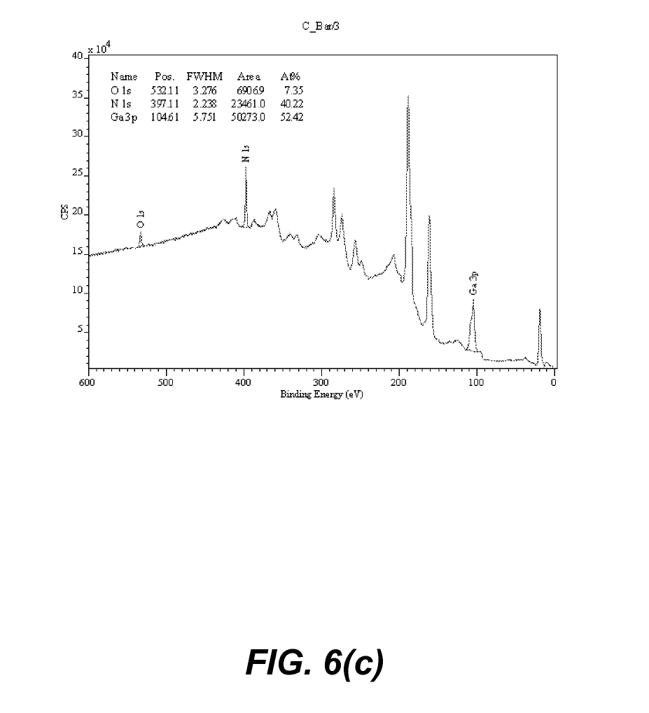

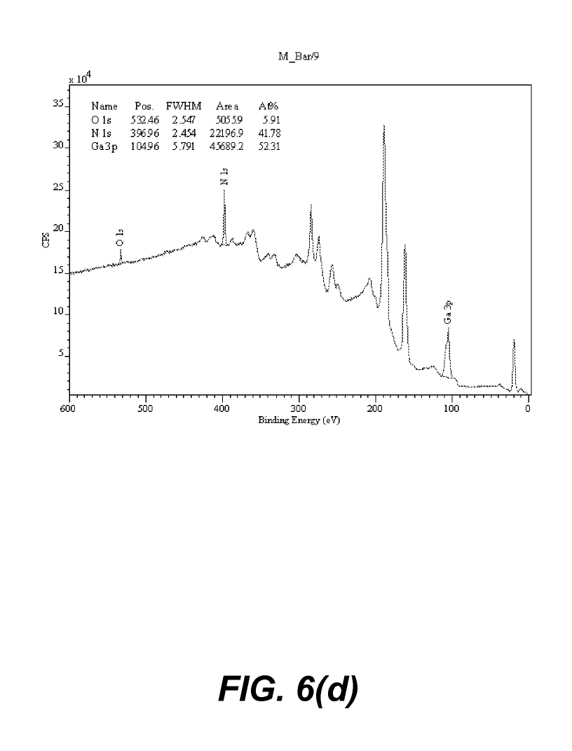

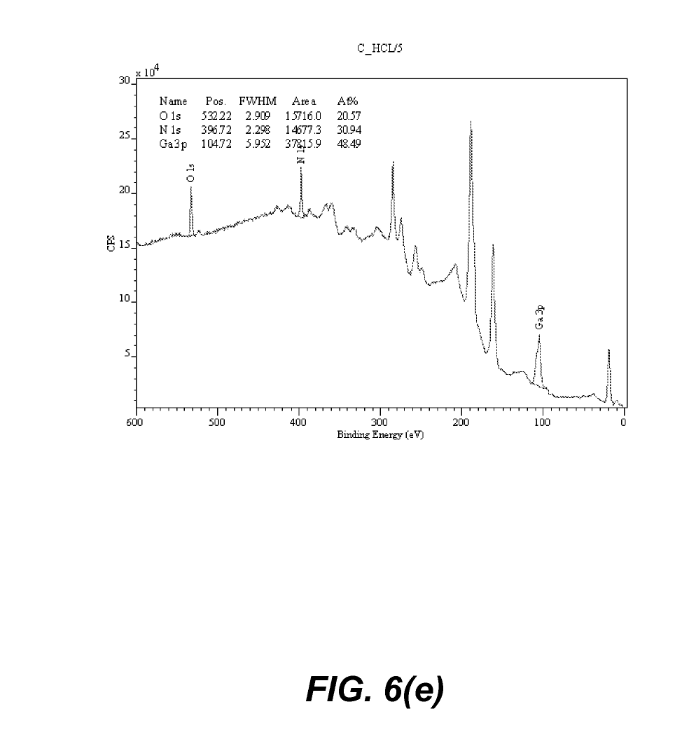

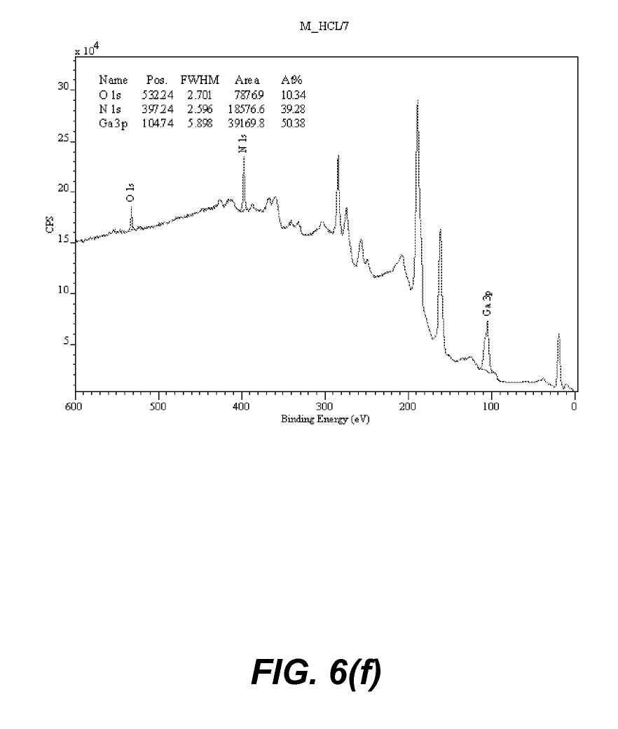

FIGS. 6(a)-6(f) are graphs of XPS data of c-plane and m-plane p-GaN with different pre-treatments, plotting CPS (×10⁴) versus binding energy in eV, wherein FIG. 6(a) is a graph of XPS data for a c-plane p-GaN contact layer fabricated using BAR and (NH₄)₂S pre-treatment, FIG. 6(b) is a graph of XPS data for an m-plane p-GaN contact layer fabricated using BAR and (NH₄)₂S pre-treatment, FIG. 6(c) is a graph of XPS data for a c-plane p-GaN contact layer fabricated using BAR pre-treatment, FIG. 6(d) is a graph of XPS data for an m-plane p-GaN contact layer fabricated using BAR pre-treatment, FIG. 6(e) is a graph of XPS data for a c-plane p-GaN contact layer fabricated using HCl pre-treatment, FIG. 6(f) is a graph of XPS data for an m-plane p-GaN contact layer fabricated using HCl pre-treatment. In each of FIGS. 6(a)-6(f), information corresponding to the O 1s peak, N 1s peak, and Ga 3p peak is shown, the information is peak emission position (pos.) in eV, peak emission FWHM in eV, area of the emission (A) in eV, and percent content of the O, N and Ga (At %). Specifically, FIGS. 6(a)-6(f) illustrate that HCl pre-treatment before p-contact metal deposition results in low O contamination on the surface of the nonpolar p-GaN contact layer.

Table 1 below illustrates that the method of the present invention may achieve lower O content on the surface of an m-plane p-GaN contact layer, as compared to a c-plane p-GaN contact layer.

TABLE 1
comparison of O content on the surface of m-plane and c-plane GaN.

| | |
|---|---|
| O content (%) | O/Ga ratio |

| Pre-treatment | m-plane | c-plane | m-plane | c-plane |
|---|---|---|---|---|
| Untreated | 27.18 | 29 | 0.67 | 0.67 |
| HC1 | 10.34 | 20.57 | 0.205 | 0.42 |
| BAR | 5.91 | 7.35 | 0.11 | 0.14 |
| BAR + NH4S | 7.03 | 8.44 | 0.138 | 0.16 |

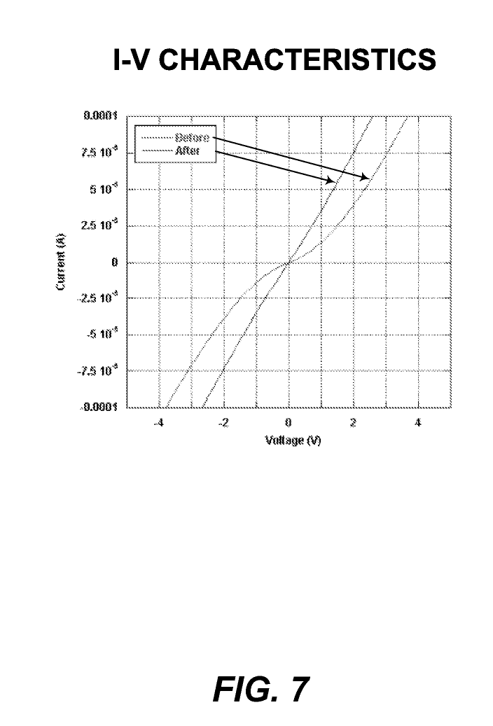

FIG. 7 is a graph of I-V characteristics of a device comprising a nonpolar p-GaN contact layer fabricated according to the present invention, with Cp2Mg flow and HCl-pre-treatment, that shows the difference between the two TLM pads with the smallest separation before, and after, applying the present invention (before and after post-growth Cp2Mg-flow during cool down and HCl treatment). Specifically, the I-V curve of FIG. 7 shows that the method of the present invention resulted in nonpolar (Al,Ga,In)N devices with much lower contact resistance and ohmic contacts.

Advantages and Improvements

Achieving low resistance p-contact is a key to high performance LEDs, LDs, p-n junction diodes, bipolar junction transistors (BJTs), heterojunction bipolar transistors (HBTs), etc. This invention has resulted in significantly improved contact properties of p-type contacts to nonpolar p-type (Al,Ga,In)N layers and is similarly applicable to p-type contacts to semipolar p-type (Al,Ga,In)N layers.

The present invention has the following advantages as compared to conventional nonpolar (Al,Ga,In)N device structures:

1. The use of Cp2Mg flow during growth cool down with N₂ and NH₃ ambient resulted in the formation of an Mg—N layer, which reduces the contact resistance significantly (as shown in FIG. 2). An Mg XPS peak is shown for the m-plane sample fabricated with Cp2Mg flow during growth cool down (FIG. 4). Furthermore, O concentration on the surface is reduced with the increase in Cp2Mg flow during the cool down.

2. The HCl pre-treatment before p-contact metal deposition resulted in (1) low O contamination on the surface of the sample, as shown in FIG. 6, and (2) lower contact resistance compared to other conventional treatment. While polar (c-plane) GaN achieves the lowest contact resistance using BAR pre-treatment, it is necessary to use HCl pre-treatment for nonpolar (m-plane) GaN, as shown in FIG. 5.

3. All the above changes resulted in electrical properties of the nonpolar (Al,Ga,In)N devices with much lower contact resistance and ohmic contacts, as compared to conventional nonpolar (Al,Ga,In)N devices, as shown in FIG. 7.

Possible Modifications

Thus, the present invention employed Cp2Mg flow after the growth of the nonpolar p-GaN based contact layer, where typical contact layer thickness can range from 10 to 100 nm and the contact layer is doped with Mg.

Other embodiments of the present invention may be used with polar, nonpolar, and semipolar (Al,Ga,In)N based electronics and optical devices, especially for the needs of low p-contact resistance. For example, the present invention can be applied to polar, nonpolar, and semipolar LEDs, LDs, transistors, etc. The present invention can be applied to any (Al,Ga,In)N devices, where low p-contact resistance is needed. The present invention can be applied to device structures containing InGaN, GaN, AlGaN, or AlInGaN layers.

Nomenclature

The terms (Al,Ga,In)N, III-nitride, Group III-nitride, nitride, Al_{(1-x-y)} GaₓIn_{y}N where 0<x<1 and 0<y<1, or AlInGaN, as used herein are intended to be broadly construed to include respective nitrides of the single species, Al, Ga and In, as well as binary, ternary and quaternary compositions of such Group III metal species. Accordingly, the term (Al,Ga,In)N comprehends the compounds AN, GaN, and InN, as well as the ternary compounds AlGaN, GaInN, and AlInN, and the quaternary compound AlGaInN, as species included in such nomenclature. When two or more of the (Al,Ga,In) component species are present, all possible compositions, including stoichiometric proportions as well as “off-stoichiometric” proportions (with respect to the relative mole fractions present of each of the (Al,Ga,In) component species that are present in the composition), can be employed within the broad scope of the invention. Accordingly, it will be appreciated that the discussion of the invention hereinafter in reference to specific (Al,Ga,In)N materials, such as GaN, is applicable to the formation of various other species of these (Al,Ga,In)N materials. Further, (Al,Ga,In)N materials within the scope of the invention may further include minor quantities of dopants and/or other impurity or inclusional materials.

Moreover, throughout this disclosure, the prefixes n− or n⁺ and p− or p⁺ before the layer material denote that the layer material is n-type or p-type doped, respectively. For example, p-GaN indicates that the GaN is p-type doped.

### REFERENCES

The following references are incorporated by reference herein.
[1] Hun et al., Appl. Phys. Lett. 78, 1942 (2001).
[2] Kim et al., J. Vac. Sci. Technol. B17(2), 497 (1999).
[3] Kim et al., J. Elec. Materials, 30, 129 (2000).
[4] Kim et al., Current Appli. Phys. 1, 385 (2001).
[5] Lim et al., Thin Solid Film, 515, 4471 (2007).
[6] Lee et al., Appli. Phys. Lett. 74, 2289 (1999).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating an (Al,Ga,In)N device, comprising:
growing a p-type layer on an (Al,Ga,In)N device, wherein the (Al,Ga,In)N device is a nonpolar or semipolar (Al,Ga,In)N device, and the p-type layer is a nonpolar or semipolar (Al,Ga,In)N layer; and
cooling the p-type layer down, in the presence of Bis(Cyclopentadienyl)Magnesium (Cp2Mg), to form a magnesium-nitride (MgₓN_{y}) layer on the p-type layer.

2. The method of claim 1, further comprising performing a metal deposition to fabricate a p-type contact on the p-type layer of the (Al,Ga,In)N device, after the cooling step, wherein the p-type contact has a contact resistivity lower than a p-type contact of a polar (Al,Ga,In)N device with a substantially similar composition.

3. The method of claim 2, further comprising performing a hydrogen chloride (HCl) pre-treatment of the p-type layer, after the cooling step and before performing the metal deposition to fabricate the p-type contact on the p-type layer.

4. The method of claim 1, wherein the cooling step is performed until a temperature of at least 700 degrees Celsius is reached.

5. The method of claim 4, wherein the cooling step is performed until a temperature of at least 500 degrees Celsius is reached.

6. The method of claim 1, wherein the cooling step is performed in a nitrogen (N₂) and ammonia (NH₃) ambient environment.

7. An (Al,Ga,In)N device fabricated according to claim 1.

8. The device of claim 7, wherein the (Al,Ga,In)N device is a light emitting diode, laser diode, p-n junction device, transistor, bipolar junction transistor or heterojunction bipolar transistor.

9. An (Al,Ga,In)N device, comprising:
a p-type contact fabricated on a p-type layer of an (Al,Ga,In)N device, wherein the (Al,Ga,In)N device is a nonpolar or semipolar (Al,Ga,In)N device, the p-type layer is a nonpolar or semipolar (Al,Ga,In)N layer, and the p-type contact has a contact resistivity lower than a p-type contact of a polar (Al,Ga,In)N device with a substantially similar composition.

10. The device of claim 9, wherein the p-type contact has a contact resistivity less than 2×10⁻³ Ohm-cm⁻².

11. The device of claim 9, wherein the p-type layer has an oxygen concentration sufficiently low to achieve the contact resistivity less than 2×10⁻³ Ohm-cm⁻².

12. A method of fabricating a (Al,Ga,In)N device, comprising:
performing a hydrogen chloride (HCl) pre-treatment of a p-type layer of the (Al,Ga,In)N device, prior to fabricating a p-type contact on the p-type layer, wherein the (Al,Ga,In)N device is a nonpolar or semipolar (Al,Ga,In)N device, and the p-type layer is a nonpolar or semipolar (Al,Ga,In)N layer.

13. The method of claim 12, wherein the p-type contact has a contact resistivity lower than a p-type contact of a polar (Al,Ga,In)N device with the same composition.

14. The method of claim 13, wherein the p-type layer has an oxygen concentration sufficiently low to achieve the contact resistivity less than 2×10⁻³ Ohm-cm⁻².

15. An (Al,Ga,In)N device fabricated according to claim 12.

16. The device of claim 15, wherein the (Al,Ga,In)N device is a light emitting diode, laser diode, p-n junction device, transistor, bipolar junction transistor or heterojunction bipolar transistor.
